(19) United States
(12) Patent Application Publication
(10) Pub. No.: US 2019/0360096 A1
(43) Pub. Date: Nov. 28, 2019

(54) PROCESS FOR THE GENERATION OF METAL-CONTAINING FILMS

(71) Applicant: BASF SE, Ludwigshafen am Rhein (DE)

(72) Inventors: David Dominique SCHWEINFURTH, Ludwigshafen (DE); Falko ABELS, Ludwigshafen (DE); Lukas MAYR, Ludwigshafen (DE); Daniel LOEFFLER, Ludwigshafen (DE); Daniel WALDMANN, Ludwigshafen (DE)

(73) Assignee: BASF SE, Ludwigshafen am Rhein (DE)

(21) Appl. No.: 16/331,593

(22) PCT Filed: Oct. 5, 2017
(86) PCT No.: PCT/EP2017/075304

§ 371 Date: Mar. 8, 2019

(30) Foreign Application Priority Data
Oct. 13, 2016 (EP) 16193697.6

(51) Int. Cl. C23C 16/455

(52) U.S. Cl. CPC C23C 16/45553

(57) ABSTRACT

The present invention is in the field of processes for the generation of thin inorganic films on substrates, in particular atomic layer deposition processes. It relates to a process for preparing metal films comprising (a) depositing a metal-containing compound from the gaseous state onto a solid substrate and (b) bringing the solid substrate with the deposited metal-containing compound in contact with a compound of general formula (la), (lb), (lc), (Id), (lla), (lib), (lie), or (lid) wherein A is O or NRN, R and R^{N} is hydrogen, an alkyl group, an alkenyl group, an aryl group, or a silyl group, R¹, R², R³, and R⁴ is hydrogen, an alkyl group, an alkenyl group, an aryl group, a silyl group, or an ester group, and E is nothing, oxygen, methylene, ethylene, or 1,3-propylene.

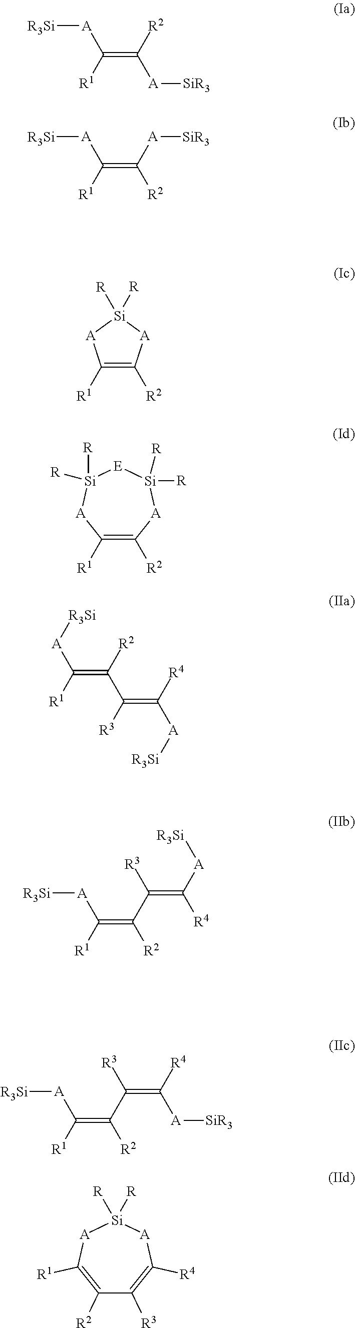

The present invention is in the field of processes for the generation of thin inorganic films on substrates, in particular atomic layer deposition processes.

With the ongoing miniaturization, e.g. in the semiconductor industry, the need for thin inorganic films on substrates increases while the requirements on the quality of such films become stricter. Thin metal films serve different purposes such as barrier layers, conducting features, or capping layers. Several methods for the generation of metal films are known. One of them is the deposition of film forming compounds from the gaseous state on a substrate. In order to bring metal atoms into the gaseous state at moderate temperatures, it is necessary to provide volatile precursors, e.g. by complexation of the metals with suitable ligands. In order to convert deposited metal complexes to metal films, it is usually necessary to expose the deposited metal complex to a reducing agent.

Typically, hydrogen gas is used to convert deposited metal complexes to metal films. While hydrogen works reasonably well as reducing agent for relatively noble metals like copper or silver, it does not yield satisfactory results for less noble metals such as titanium or aluminum.

US 2015/0 004 315 A1 discloses reducing agents with a quinoid structure. However, these reducing agents leave a significant amount of impurities in the metal film which is unfavorable for some applications, for example microchip production.

H. T. Dieck et al. disclose in Chemische Berichte volume 116 (1983), page 136-145 1,2-diaminoethene derivatives. However, they are not used as reducing agent in film formation processes.

US 2016/0 115 593 A1 disclose amino(iodo)silane precursors for use to deposit silicon-containing films. These compounds are nevertheless not useful as reducing agents. Also, halogens are unfavorable for some applications.

It was therefore an object of the present invention to provide reducing agents, which are capable of reducing surface-bound metal atoms to the metallic state leaving less impurity in the metal film. The reducing agents should be easy to handle; in particular, it should be possible to vaporize them with as little decomposition as possible. Furthermore, the reducing agent should be versatile, so it can be applied to a broad range of different metals including electropositive metals.

These objects were achieved by a process for preparing metal-containing films comprising

(a) depositing a metal-containing compound from the gaseous state onto a solid substrate and
(b) bringing the solid substrate with the deposited metal-containing compound in contact with a compound of general formula (Ia), (Ib), (Ic), (Id), (IIa), (IIb), (IIc), or (IId)

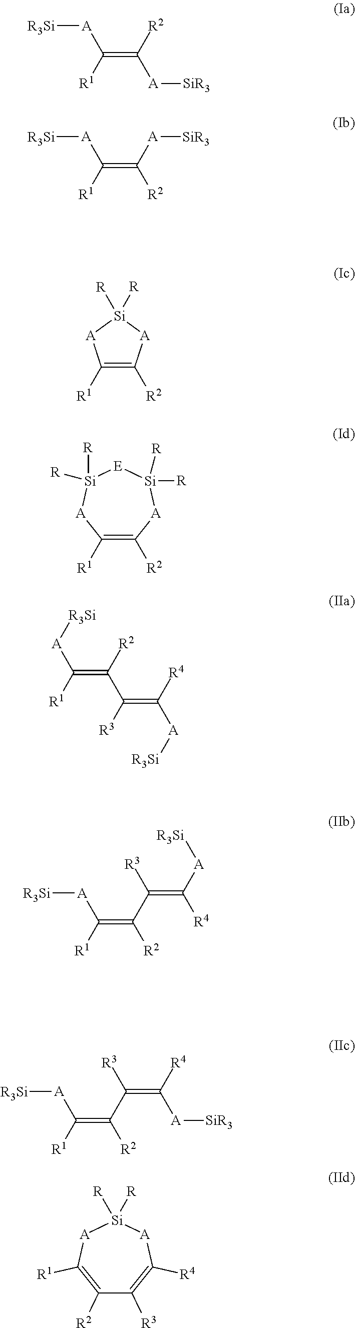

wherein A is O or NR^{N},
R and R^{N} is hydrogen, an alkyl group, an alkenyl group, an aryl group, or a silyl group,
R¹ and R² is hydrogen, an alkyl group, an alkenyl group, an aryl group, a silyl group, or an ester group, and
E is nothing, oxygen, methylene, ethylene, or 1,3-propylene.

The present invention further relates to the use of a compound of general formula (Ia), (Ib), (Ic), (Id), (IIa), (IIb), (IIc), or (IId) as reducing agent in a film forming process,

wherein A is O or NR^{N},
R and R^{N} is hydrogen, an alkyl group, an alkenyl group, an aryl group, or a silyl group,
R¹, R², R³, and R⁴ is hydrogen, an alkyl group, an alkenyl group, an aryl group, a silyl group, or an ester group, and
E is nothing, oxygen, methylene, ethylene, or 1,3-propylene.

The present invention further relates to a compound of general formula (Id), wherein A is O or NR^{N},

R and R^{N} is hydrogen, an alkyl group, an alkenyl group, an aryl group, or a silyl group,
R¹, R², R³, and R⁴ is hydrogen or an alkyl group, and
E is nothing, oxygen, methylene, ethylene, or 1,3-propylene.

The present invention further relates to a compound of general formula (IIa), (IIb), (IIc) or (IId) wherein A is NR^{N},

R and R^{N} is hydrogen, an alkyl group, an alkenyl group, an aryl group, or a silyl group,
R¹, R², R³, and R⁴ is hydrogen, an alkyl group, an alkenyl group, an aryl group, a silyl group, or in case of general formula (IIa), (IIb) or (IIc) an ester group.

Preferred embodiments of the present invention can be found in the description and the claims. Combinations of different embodiments fall within the scope of the present invention.

The process according to the present invention includes depositing a metal-containing compound from the gaseous state onto a solid substrate. The metal-containing compound contains at least one metal atom. Metals include Li, Be, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Cs, Ba, La, Ce, Pr, Nd, Pm, Sm, Eu, Gd, Tb, Dy, Ho, Er, Tm, Yb, Lu, Hf, Ta, W, Re, Os Ir, Pt, Au, Hg, Tl, Bi. Preferably, the metal-containing compound contains a metal which is more electropositive than Cu, more preferably more electropositive than Ni. In particular, the metal-containing compound contains Ti, Ta, Mn, Mo, W, or Al. It is possible that more than one metal-containing compound is deposited on the surface, either simultaneously or consecutively. If more than one metal-containing compound is deposited on a solid substrate it is possible that all metal-containing compounds contain the same metal or different ones, preferably they contain the same metal.

Any metal-containing compound, which can be brought into the gaseous state, is suitable. These compounds include alkyl metals such as dimethyl zinc, trimethylaluminum; metal alkoxylates such as tetramethoxy silicon, tetra-isopropoxy zirconium or tetra-iso-propoxy titanium; cyclopentadiene complexes like pentamethylcyclopendienyl-trimethoxy titanium or di(ethylcycopentadienyl) manganese; metal carbenes such as tantalum-pentaneopentylat or bisimidazolidinylen ruthenium chloride; metal halogenides such as tantalum pentachloride or titanium tetrachloride; carbon monoxide complexes like hexacarbonyl chromium or tetracarbonyl nickel; amine complexes such as di-(bis-tertbuylamino)-di-(bismethylamino) molybdenum, di-(bistertbuylamino)-di-(bismethylamino) tungsten or tetra-dimethylamino titanium; dione complexes such as triacetylacetonato aluminum or bis(2,2,6,6-tetramethyl-3,5-heptanedionato) manganese. Alkyl metals, cyclopentadiene complexes, metal halogenides and amine complexes are preferred. It is preferred that the molecular weight of the metal-containing compound is up to 1000 g/mol, more preferred up to 800 g/mol, in particular up to 600 g/mol, such as up to 500 g/mol.

The solid substrate can be any solid material. These include for example metals, semimetals, oxides, nitrides, and polymers. It is also possible that the substrate is a mixture of different materials. Examples for metals are aluminum, steel, zinc, and copper. Examples for semimetals are silicon, germanium, and gallium arsenide. Examples for oxides are silicon dioxide, titanium dioxide, and zinc oxide. Examples for nitrides are silicon nitride, aluminum nitride, titanium nitride, and gallium nitride. Examples for polymers are polyethylene terephthalate (PET), polyethylene naphthalene-dicarboxylic acid (PEN), and polyamides.

The solid substrate can have any shape. These include sheet plates, films, fibers, particles of various sizes, and substrates with trenches or other indentations. The solid substrate can be of any size. If the solid substrate has a particle shape, the size of particles can range from below 100 nm to several centimeters, preferably from 1 μm to 1 mm. In order to avoid particles or fibers to stick to each other while the metal-containing compound is deposited onto them, it is preferably to keep them in motion. This can, for example, be achieved by stirring, by rotating drums, or by fluidized bed techniques.

According to the present invention the solid substrate with the deposited metal-containing compound is brought in contact with a compound of general formula (Ia), (lb), (Ic), (Id), (IIa), (IIb), (IIc), or (IId). Typically the compound of general formula (Ia), (Ib), (Ic), (Id), (IIa), (IIb), (IIc), or (IId) acts as a reducing agent on the deposited metal-containing compound. The metal-containing compound is usually reduced to a metal. Therefore, the process for preparing metal-containing films is preferably a process for preparing metal films. Metal films in the context of the present invention are metal-containing films with high electrical conductivity, usually at least 10⁴ S/m, preferably at least 10⁵ S/m, in particular at least 10⁶ S/m.

The compound of general formula (Ia), (Ib), (Ic), (Id), (IIa), (IIb), (IIc), or (IId) has a low tendency to form a permanent bond with the surface of the solid substrate with the deposited metal-containing compound. As a result, the metal-containing film hardly gets contaminated with the reaction products of the compound of general formula (Ia), (Ib), (Ic), (Id), (IIa), (IIb), (IIc), or (IId). Preferably, the metal-containing film contains in sum less than 5 weight-% of elements present in the compound of general formula (Ia), (Ib), (Ic), (Id), (IIa), (IIb), (IIc), or (IId) with regard to the metal-containing film, more preferably less than 1 wt.-%, in particular less than 0.1 wt.-%, such as 0.01 wt.-%.

R and R^{N} in the compound of general formula (Ia), (Ib), (Ic), (Id), (IIa), (IIb), (IIc), or (IId) is hydrogen, an alkyl group, an alkenyl group, an aryl group, or a silyl group; R¹, R², R³, and R⁴ is hydrogen, an alkyl group, an alkenyl group, an aryl group, a silyl group, or an ester group. R, R¹, R², R³, R⁴ and R^{N} can be the same or different to each other. The compounds of general formula (Ia), (Ib), (Ic), (Id), (IIa), (IIb), (IIc), or (IId) contain six R, namely three per silicon atom. It is possible that all R are the same, or that some R are the same and the remaining R are different, or that all R are different to each other. Preferably, all R attached to one silicon atom are the same while the R attached to different silicon atoms can be different, more preferably all R are the same. Preferably, R is hydrogen, methyl, or ethyl.

An alkyl group can be linear or branched. Examples for a linear alkyl group are methyl, ethyl, n-propyl, n-butyl, n-pentyl, n-hexyl, n-heptyl, n-octyl, n-nonyl, n-decyl. Examples for a branched alkyl group are iso-propyl, iso-butyl, sec-butyl, tert-butyl, 2-methyl-pentyl, neo-pentyl, 2-ethylhexyl, cyclopropyl, cyclohexyl, indanyl, norbornyl. Preferably, the alkyl group is a C₁ to C₈ alkyl group, more preferably a C₁ to C₆ alkyl group, in particular a C₁ to C₄ alkyl group, such as methyl, ethyl, iso-propyl or tert-butyl.

An alkenyl group contains at least one carbon-carbon double bond. The double bond can include the carbon atom with which R is bound to the rest of the molecule, or it can be placed further away from the place where R is bound to the rest of the molecule. Alkenyl groups can be linear or branched. Examples for linear alkenyl groups in which the double bond includes the carbon atom with which R is bound to the rest of the molecule include 1-ethenyl, 1-propenyl, 1-n-butenyl, 1-n-pentenyl, 1-n-hexenyl, 1-n-heptenyl, 1-n-octenyl. Examples for linear alkenyl groups in which the double bond is placed further away from the place where R is bound to the rest of the molecule include 1-n-propen-3-yl, 2-buten-1-yl, 1-buten-3-yl, 1-buten-4-yl, 1-hexen-6-yl. Examples for branched alkenyl groups in which the double bond includes the carbon atom with which R is bound to the rest of the molecule include 1-propen-2-yl, 1-n-buten-2-yl, 2-buten-2-yl, cyclopenten-1-yl, cyclohexen-1-yl. Examples for branched alkenyl groups in which the double bond is placed further away from the place where R is bound to the rest of the molecule include 2-methyl-1-buten-4-yl, cyclopenten-3-yl, cyclohexene-3-yl. Examples for an alkenyl group with more than one double bonds include 1,3-butadien-1-yl, 1,3-butadien-2-yl, cylopentadien-5-yl.

Aryl groups include aromatic hydrocarbons such as phenyl, naphthalyl, anthrancenyl, phenanthrenyl groups and heteroaromatic groups such as pyrryl, furanyl, thienyl, pyridinyl, quinoyl, benzofuryl, benzothiophenyl, thienothienyl. Several of these groups or combinations of these groups are also possible like biphenyl, thienophenyl or furanylthienyl. Aryl groups can be substituted for example by halogens like fluoride, chloride, bromide, iodide; by pseudohalogens like cyanide, cyanate, thiocyanate; by alcohols; alkyl chains or alkoxy chains. Aromatic hydrocarbons are preferred, phenyl is more preferred.

A silyl group is a silicon atom with typically three substituents. Preferably a silyl group has the formula SiX₃, wherein X is independent of each other hydrogen, an alkyl group, an aryl group or a silyl group. It is possible that all three X are the same or that two A are the same and the remaining X is different or that all three X are different to each other, preferably all X are the same. Alkyl and aryl groups are as described above. Examples for siliyl groups include SiH₃, methylsilyl, trimethylsilyl, triethylsilyl, tri-n-propylsilyl, tri-iso-propylsilyl, tricyclohexylsilyl, dimethyl-tert-butylsilyl, dimethylcyclohexylsilyl, methyl-di-iso-propylsilyl, triphenylsilyl, phenylsilyl, dimethylphenylsilyl, pentamethyldisilyl.

An ester group is an alkyl carboxylate, i.e. C(═O)—O-Alk, wherein Alk is an alkyl group as described above. Preferably, Alk is methyl, ethyl, n-propyl, iso-propyl, n-butyl, iso-butyl, tert-butyl, or neo-pentyl, more preferably methyl, so the ester group is methyl carboxylate.

Preferably, R¹, R², R³ and R⁴ are hydrogen, methyl, tert-butyl, trimethylsilyl or methylcarboxylate. This means, that preferably R¹, R² in compound of general formula (Ia), (Ib), (Ic), (Id) are hydrogen, methyl, tert-butyl, trimethylsilyl or methylcarboxylate and that preferably R¹, R², R³ and R⁴ in the compound of general formula (IIa), (IIb), (IIc), or (IId) are hydrogen, methyl, tert-butyl, trimethylsilyl or methylcarboxylate. More preferably, R¹, R², R³ and R⁴ are hydrogen.

A in the compound of general formula (Ia), (Ib), (Ic), (Id), (IIa), (IIb), (IIc), or (IId) is O or NR^{N}, i.e. oxygen or nitrogen bearing the substituent R^{N}. The two A can be the same or different to each other, preferably they are the same. Preferably A is NR^{N}. R^{N} is defined above. Preferably, R^{N} is an alkyl group or a silyl group, in particular tert-butyl, neo-pentyl, or trimethylsilyl.

E in the compound of general formula (Id) or (IId) is nothing, oxygen, methylene, i.e. —CH₂—, ethylene, i.e. —CH₂—CH₂—, or 1,3-propylene, i.e. —CH₂—CH₂—CH₂—, preferably oxygen or methylene, in particular methylene.

The compound of general formula (Ia), (Ib), (Ic), (Id), (IIa), (IIb), (IIc), or (IId) preferably has a molecular weight of not more than 1000 g/mol, more preferably not more than 800 g/mol, even more preferably not more than 600 g/mol, in particular not more than 500 g/mol.

Some preferred examples of compounds of general formula (Ia) are shown below

TABLE 1
Me stand for methyl, i-Pr for iso-propyl, t-Bu for tert-butyl, TMS
for trimethylsilyl, DMP for 2,6-dimethylphenyl, Np for neo-pentyl.

| No. | R | R¹ | R² | A |
|---|---|---|---|---|
| Ia-1 | Me | H | H | N—t-Bu |
| Ia-2 | Me | H | H | N—TMS |
| Ia-3 | Me | H | H | O |
| Ia-4 | Me | Me | Me | N—t-Bu |
| Ia-5 | Me | H | H | N—DMP |
| Ia-6 | Me | H | H | N—Np |
| Ia-7 | Et | H | H | N—t-Bu |
| Ia-8 | Me | Me | Me | O |
| Ia-9 | Me | H | H | N—i-Pr |
| Ia-10 | Me | Me | Me | N—i-Pr |
| Ia-11 | Et | H | H | N—i-Pr |
| Ia-12 | Et | Me | Me | N—i-Pr |
| Ia-13 | Et | H | H | N—t-Bu |
| Ia-14 | Me | Me | Me | N—Np |
| Ia-15 | Et | H | H | N—Np |
| Ia-16 | Et | Me | Me | N—Np |
| Ia-17 | Et | H | H | N—DMP |
| Ia-18 | Me | Me | Me | N—DMP |
| Ia-19 | Et | Me | Me | N—DMP |

Some preferred examples of compounds of general formula (Ib) are shown below

TABLE 2
Me stand for methyl, t-Bu for tert-butyl, TMS for trimethylsilyl,
DMP for 2,6-dimethylphenyl, Np for neo-pentyl.

| No. | R | R¹ | R² | A |
|---|---|---|---|---|
| Ib-1 | Me | H | H | N—t-Bu |
| Ib-2 | Me | H | H | N—TMS |
| Ib-3 | Me | H | H | O |
| Ib-4 | Me | Me | Me | N—t-Bu |
| Ib-5 | Me | H | H | N—DMP |
| Ib-6 | Me | H | H | N—Np |
| Ib-7 | Et | H | H | N—t-Bu |
| Ib-8 | Me | Ph | Ph | N—Ph |

Some preferred examples of compounds of general formula (Ic) are shown below

TABLE 3
Me stand for methyl, i-Pr for iso-propyl, t-Bu for tert-butyl, TMS
for trimethylsilyl, DMP for 2,6-dimethylphenyl, Np for neo-pentyl.

| No. | R | R¹ | R² | A |
|---|---|---|---|---|
| Ic-1 | Me | H | H | N—t-Bu |
| Ic-2 | Me | H | H | N—TMS |
| Ic-3 | Me | H | H | O |
| Ic-4 | Me | Me | Me | N—t-Bu |
| Ic-5 | Me | H | H | N—DMP |
| Ic-6 | Me | H | H | N—Np |
| Ic-7 | Et | H | H | N—t-Bu |
| Ic-8 | Me | H | H | N—t-Bu |
| Ic-9 | Me | H | H | N—DMP |
| Ic-10 | Me | Me | Me | N(i-Pr) |
| Ic-11 | Me | Me | Me | N—Np |
| Ic-12 | Et | H | H | N—DMP |
| Ic-13 | Et | H | H | N—i-Pr |
| Ic-14 | Et | Me | Me | N—i-Pr |
| Ic-15 | Et | Me | Me | N—t-Bu |
| Ic-16 | Et | H | H | N—Np |
| Ic-17 | Et | Me | Me | N—Np |

Some preferred examples of compounds of general formula (Id) are shown below

TABLE 4
Me stand for methyl, t-Bu for tert-butyl, TMS for trimethylsilyl,
DMP for 2,6-dimethylphenyl, Np for neo-pentyl.

| No. | R | R¹ | R² | A | E |
|---|---|---|---|---|---|
| Id-1 | Me | H | H | N—t-Bu | CH₂ |
| Id-2 | Me | H | H | N—TMS | CH₂ |
| Id-3 | Me | H | H | O | CH₂ |
| Id-4 | Me | Me | Me | N—t-Bu | CH₂ |
| Id-5 | Me | H | H | N—t-Bu | O |
| Id-6 | Me | H | H | N—TMS | O |
| Id-7 | Me | H | H | O | O |
| Id-8 | Me | Me | Me | N—t-Bu | O |
| Id-9 | Me | H | H | N—Np | CH₂ |
| Id-10 | Me | H | H | N—Np | O |
| Id-11 | Me | H | H | N—DMP | CH₂ |
| Id-12 | Me | H | H | N—DMP | O |

Some preferred examples of compounds of general formula (IIa) are shown below

TABLE 5

| No. | R | R¹ | R² | R³ | R⁴ | A |
|---|---|---|---|---|---|---|
| lla-1 | Me | H | Me | Me | H | N-t-Bu |
| lla-2 | Me | H | Me | Me | H | N-TMS |
| lla-3 | Me | H | Me | Me | H | O |
| lla-4 | Me | H | Me | Me | H | N-Np |
| lla-5 | Me | H | Me | Me | H | N-DMP |
| lla-6 | Me | Ph | H | H | Ph | O |

Me stand for methyl,
t-Bu for tert-butyl,
TMS for trimethylsilyl
DMP for 2,6-dime-thylphenyl,
Np for neo-pentyl.

Some preferred examples of compounds of general formula (IIb) are shown below

TABLE 6

| No. | R | R¹ | R² | R³ | R⁴ | A |
|---|---|---|---|---|---|---|
| llb-1 | Me | H | Me | Me | H | N-t-Bu |
| llb-2 | Me | H | Me | Me | H | N-TMS |
| llb-3 | Me | H | Me | Me | H | O |
| llc-4 | Me | H | Me | Me | H | N-Np |
| llc-5 | Me | H | Me | Me | H | N-DMP |
| llc-6 | Me | Me | H | H | Me | O |

Me stand for methyl,
t-Bu for tert-butyl,
TMS for trimethylsilyl,
DMP for 2,6-dime-thylphenyl,
Np for neo-pentyl.

Some preferred examples of compounds of general formula (IIc) are shown below

TABLE 7

| No. | R | R¹ | R² | R³ | R⁴ | A |
|---|---|---|---|---|---|---|
| llc-1 | Me | H | Me | Me | H | N-t-Bu |
| llc-2 | Me | H | Me | Me | H | N-TMS |
| llc-3 | Me | H | Me | Me | H | O |
| llc-4 | Me | H | Me | Me | H | N-Np |
| llc-5 | Me | H | Me | Me | H | N-Np |

Me stand for methyl,
t-Bu for tert-butyl,
TMS for trimethylsilyl,
DMP for 2,6-dime-thylphenyl,
ND for neo-pentyl.

Some preferred examples of compounds of general formula (IId) are shown below

TABLE 8

| No. | R | R¹ | R² | R³ | R⁴ | A |
|---|---|---|---|---|---|---|
| lld-1 | Me | H | Me | Me | H | N-t-Bu |
| lld-2 | Me | H | Me | Me | H | N-TMS |
| lld-3 | Me | H | Me | Me | H | O |
| lld-4 | Me | H | CO₂Me | CO₂Me | H | N-t-Bu |
| lld-5 | Me | H | SiMe₃ | SiMe₃ | H | N-t-Bu |
| lld-6 | Me | H | t-Bu | t-Bu | H | N-t-Bu |
| lld-7 | Me | H | H | H | H | N-t-Bu |
| lld-8 | Me | H | CO₂Me | CO₂Me | H | N-Np |
| lld-9 | Me | H | SiMe₃ | SiMe₃ | H | N-Np |
| lld-10 | Me | H | t-Bu | t-Bu | H | N-Np |
| lld-11 | Me | H | H | H | H | N-Np |
| lld-12 | Me | H | CO₂Me | CO₂Me | H | N-DMP |
| lld-13 | Me | H | SiMe₃ | SiMe₃ | H | N-DMP |
| lld-14 | Me | H | t-Bu | t-Bu | H | N-DMP |
| lld-15 | Me | H | H | H | H | N-DMP |
| lld-16 | Me | Ph | Ph | Ph | Ph | O |

Me stand for methyl,
t-Bu for tert-butyl,
TMS for trimethylsilyl,
DMP for 2,6-dime-thylphenyl,
Np for neo-pentyl.

The synthesis of some of the compound of general formula (Ia), (Ib), (Ic), (Id), (IIa), (IIb), (IIc), or (IId) are for example disclosed by H. T. Dieck et al. in Chemische Berichte volume 116 (1983), page 136-145 or in Chemische Berichte volume 120 (1987), page 795-801.

Both the metal-containing compound and the compound of general formula (Ia), (Ib), (Ic), (Id), (IIa), (IIb), (IIc), or (IId) used in the process according to the present invention are used at high purity to achieve the best results. High purity means that the substance used contains at least 90 wt.-% metal-containing compound or compound of general formula (Ia), (Ib), (Ic), (Id), (IIa), (IIb), (IIc), or (IId), preferably at least 95 wt.-%, more preferably at least 98 wt.-%, in particular at least 99 wt.-%. The purity can be determined by elemental analysis according to DIN 51721 (Prüfung fester Brennstoffe—Bestimmung des Gehaltes an Kohlenstoff and Wasserstoff—Verfahren nach Radmacher-Hoverath, August 2001).

The metal-containing compound or the compound of general formula (Ia), (Ib), (Ic), (Id), (IIa), (IIb), (IIc), or (IId) can be deposited or brought in contact with the solid substrate from the gaseous state. They can be brought into the gaseous state for example by heating them to elevated temperatures. In any case a temperature below the decomposition temperature of the metal-containing compound or the compound of general formula (Ia), (Ib), (Ic), (Id), (IIa), (IIb), (IIc), or (IId) has to be chosen. In this context, the oxidation of the compound of general formula (Ia), (Ib), (Ic), (Id), (IIa), (IIb), (IIc), or (IId) is not regarded as decomposition. A decomposition is a reaction in which the metal-containing compound or the compound of general formula (Ia), (Ib), (Ic), (Id), (IIa), (IIb), (IIc), or (IId) is converted to an undefined variety of different compounds. Preferably, the heating temperature ranges from 0° C. to 300° C., more preferably from 10° C. to 250° C., even more preferably from 20° C. to 200° C., in particular from 30° C. to 150° C.

Another way of bringing the metal-containing compound or the compound of general formula (Ia), (Ib), (Ic), (Id), (IIa), (IIb), (IIc), or (IId) into the gaseous state is direct liquid injection (DLI) as described for example in US 2009/0 226 612 A1. In this method the metal-containing compound or the compound of general formula (Ia), (Ib), (Ic), (Id), (IIa), (IIb), (IIc), or (IId) is typically dissolved in a solvent and sprayed in a carrier gas or vacuum. If the vapor pressure of metal-containing compound or the compound of general formula (Ia), (Ib), (Ic), (Id), (IIa), (IIb), (IIc), or (IId) and the temperature are sufficiently high and the pressure is sufficiently low the metal-containing compound or the compound of general formula (Ia), (Ib), (Ic), (Id), (IIa), (IIb), (IIc), or (IId) is brought into the gaseous state. Various solvents can be used provided that the metal-containing compound or the compound of general formula (Ia), (Ib), (Ic), (Id), (IIa), (IIb), (IIc), or (IId) shows sufficient solubility in that solvent such as at least 1 g/l, preferably at least 10 g/l, more preferably at least 100 g/l. Examples for these solvents are coordinating solvents such as tetrahydrofuran, dioxane, diethoxyethane, pyridine or non-coordinating solvents such as hexane, heptane, benzene, toluene, or xylene. Solvent mixtures are also suitable.

Alternatively, the metal-containing compound or the compound of general formula (Ia), (Ib), (Ic), (Id), (IIa), (IIb), (IIc), or (IId) can be brought into the gaseous state by direct liquid evaporation (DLE) as described for example by J. Yang et al. (Journal of Materials Chemistry, 2015). In this method, the metal-containing compound or the compound of general formula (Ia), (Ib), (Ic), (Id), (IIa), (IIb), (IIc), or (IId) is mixed with a solvent, for example a hydrocarbon such as tetradecane, and heated below the boiling point of the solvent. By evaporation of the solvent, the metal-containing compound or the compound of general formula (Ia), (Ib), (Ic), (Id), (IIa), (IIb), (IIc), or (IId) is brought into the gaseous state. This method has the advantage that no particulate contaminants are formed on the surface.

It is preferred to bring the metal-containing compound or the compound of general formula (Ia), (Ib), (Ic), (Id), (IIa), (IIb), (IIc), or (IId) into the gaseous state at decreased pressure. In this way, the process can usually be performed at lower heating temperatures leading to decreased decomposition of the metal-containing compound or the compound of general formula (Ia), (Ib), (Ic), (Id), (IIa), (IIb), (IIc), or (IId). It is also possible to use increased pressure to push the metal-containing compound or the compound of general formula (Ia), (Ib), (Ic), (Id), (IIa), (IIb), (IIc), or (IId) in the gaseous state towards the solid substrate. Often, an inert gas, such as nitrogen or argon, is used as carrier gas for this purpose. Preferably, the pressure is 10 bar to 10⁻⁷ mbar, more preferably 1 bar to 10⁻³ mbar, in particular 1 to 0.01 mbar, such as 0.1 mbar.

It is also possible that the metal-containing compound or the compound of general formula (Ia), (Ib), (Ic), (Id), (IIa), (IIb), (IIc), or (IId) is deposited or brought in contact with the solid substrate from solution. Deposition from solution is advantageous for compounds which are not stable enough for evaporation. However, the solution needs to have a high purity to avoid undesirable contaminations on the surface. Deposition from solution usually requires a solvent which does not react with the metal-containing compound or the compound of general formula (Ia), (Ib), (Ic), (Id), (IIa), (IIb), (IIc), or (IId). Examples for solvents are ethers like diethyl ether, methyl-tert-butylether, tetrahydrofurane, dioxane; ketones like acetone, methylethylketone, cyclopentanone; esters like ethyl acetate; lactones like 4-butyrolactone; organic carbonates like diethylcarbonate, ethylene carbonate, vinylenecarbonate; aromatic hydrocarbons like benzene, toluene, xylene, mesitylene, ethylbenzene, styrene; aliphatic hydrocarbons like n-pentane, n-hexane, cyclohexane, iso-undecane, decaline, hexadecane. Ethers are preferred, in particular tetrahydrofurane. The concentration of the metal-containing compound or the compound of general formula (Ia), (Ib), (Ic), (Id), (IIa), (IIb), (IIc), or (IId) depend among others on the reactivity and the desired reaction time. Typically, the concentration is 0.1 mmol/l to 10 mol/I, preferably 1 mmol/l to 1 mol/I, in particular 10 to 100 mmol/l.

For the deposition process, it is possible to sequentially contact the solid substrate with a metal-containing compound and with a solution containing a compound of general formula (Ia), (Ib), (Ic), (Id), (IIa), (IIb), (IIc), or (IId). Bringing the solid substrate in contact to the solutions can be performed in various ways, for example by dip-coating or spin-coating. Often it is useful to remove excess metal-containing compound or the compound of general formula (Ia), (Ib), (Ic), (Id), (IIa), (IIb), (IIc), or (IId), for example by rinsing with the pristine solvent. The reaction temperature for solution deposition is typically lower than for deposition from the gaseous or aerosol phase, typically 20 to 150° C., preferably 50 to 120° C., in particular 60 to 100° C. In some cases it can be useful to anneal the film after several deposition steps, for example by heating to temperatures of 150 to 500° C., preferably 200 to 450° C., for 10 to 30 minutes.

The deposition of the metal-containing compound takes place if the substrate comes in contact with the metal-containing compound. Generally, the deposition process can be conducted in two different ways: either the substrate is heated above or below the decomposition temperature of the metal-containing compound. If the substrate is heated above the decomposition temperature of the metal-containing compound, the metal-containing compound continuously decomposes on the surface of the solid substrate as long as more metal-containing compound in the gaseous state reaches the surface of the solid substrate. This process is typically called chemical vapor deposition (CVD). Usually, an inorganic layer of homogeneous composition, e.g. the metal oxide or nitride, is formed on the solid substrate as the organic material is desorbed from the metal M. This inorganic layer is then converted to the metal layer by bringing it in contact with the compound of general formula (Ia), (Ib), (Ic), (Id), (IIa), (IIb), (IIc), or (IId). Typically the solid substrate is heated to a temperature in the range of 300 to 1000° C., preferably in the range of 350 to 600° C.

Alternatively, the substrate is below the decomposition temperature of the metal-containing compound. Typically, the solid substrate is at a temperature equal to or slightly above the temperature of the place where the metal-containing compound is brought into the gaseous state, often at room temperature or only slightly above. Preferably, the temperature of the substrate is 5° C. to 40° C. higher than the place where the metal-containing compound is brought into the gaseous state, for example 20° C. Preferably, the temperature of the substrate is from room temperature to 400° C., more preferably from 100 to 300° C., such as 150 to 220° C.

The deposition of metal-containing compound onto the solid substrate is either a physisorption or a chemisorption process. Preferably, the metal-containing compound is chemisorbed on the solid substrate. One can determine if the metal-containing compound chemisorbs to the solid substrate by exposing a quartz microbalance with a quartz crystal having the surface of the substrate in question to the metal-containing compound in the gaseous state. The mass increase is recorded by the eigen frequency of the quartz crystal. Upon evacuation of the chamber in which the quartz crystal is placed the mass should not decrease to the initial mass, but up to a monolayer of the residual metal-containing compound remains if chemisorption has taken place. In most cases where chemisorption of the metal-containing compound to the solid substrate occurs, the x-ray photoelectron spectroscopy (XPS) signal (ISO 13424 EN—Surface chemical analysis—X-ray photoelectron spectroscopy—Reporting of results of thin-film analysis; October 2013) of M changes due to the bond formation to the substrate.

If the temperature of the substrate in the process according to the present invention is kept below the decomposition temperature of the metal-containing compound, typically a monolayer is deposited on the solid substrate. Once a molecule of the metal-containing compound is deposited on the solid substrate further deposition on top of it usually becomes less likely. Thus, the deposition of the metal-containing compound on the solid substrate preferably represents a self-limiting process step. The typical layer thickness of a self-limiting deposition processes step is from 0.01 to 1 nm, preferably from 0.02 to 0.5 nm, more preferably from 0.03 to 0.4 nm, in particular from 0.05 to 0.2 nm. The layer thickness is typically measured by ellipsometry as described in PAS 1022 DE (Referenzverfahren zur Bestimmung von optischen and dielektrischen Materialeigenschaften sowie der Schichtdicke dünner Schichten mittels Ellipsometrie; February 2004).

A deposition process comprising a self-limiting process step and a subsequent self-limiting reaction is often referred to as atomic layer deposition (ALD). Equivalent expressions are molecular layer deposition (MLD) or atomic layer epitaxy (ALE). Hence, the process according to the present invention is preferably an ALD process. The ALD process is described in detail by George (Chemical Reviews 110 (2010), 111-131).

A particular advantage of the process according to the present invention is that the compound of general formula (I) is very versatile, so the process parameters can be varied in a broad range. Therefore, the process according to the present invention includes both a CVD process as well as an ALD process.

Preferably, after deposition of a metal-containing compound on the solid substrate and before bringing the solid substrate with the deposited metal-containing compound in contact with a reducing agent, the solid substrate with the deposited metal-containing compound is brought in contact with an acid in the gaseous phase. Without being bound by a theory, it is believed that the protonation of the ligands of the metal-containing compound facilitates its decomposition and reduction. Preferably, carboxylic acids are used such as formic acid, acetic acid, propionic acid, butyric acid, or trifluoroacetic acid, in particular formic acid.

Often it is desired to build up thicker layers than those just described. In order to achieve this the process comprising (a) and (b), which can be regarded as one ALD cycle, are preferably performed at least twice, more preferably at least 10 times, in particular at least 50 times. Usually, the process comprising (a) and (b) is performed not more than 1000 times.

The deposition of the metal-containing compound or its contacting with a reducing agent can take from milliseconds to several minutes, preferably from 0.1 second to 1 minute, in particular from 1 to 10 seconds. The longer the solid substrate at a temperature below the decomposition temperature of the metal-containing compound is exposed to the metal-containing compound the more regular films formed with less defects. The same applies for contacting the deposited metal-containing compound to the reducing agent.

The process according to the present invention yields a metal film. A film can be only one monolayer of a metal or be thicker such as 0.1 nm to 1 μm, preferably 0.5 to 50 nm. A film can contain defects like holes. These defects, however, generally constitute less than half of the surface area covered by the film. The film preferably has a very uniform film thickness which means that the film thickness at different places on the substrate varies very little, usually less than 10%, preferably less than 5%. Furthermore, the film is preferably a conformal film on the surface of the substrate. Suitable methods to determine the film thickness and uniformity are XPS or ellipsometry.

The film obtained by the process according to the present invention can be used in an electronic element. Electronic elements can have structural features of various sizes, for example from 100 nm to 100 μm. The process for forming the films for the electronic elements is particularly well suited for very fine structures. Therefore, electronic elements with sizes below 1 μm are preferred. Examples for electronic elements are field-effect transistors (FET), solar cells, light emitting diodes, sensors, or capacitors. In optical devices such as light emitting diodes or light sensors the film obtained by the process according to the present invention serves to increase the reflective index of the layer which reflects light.

Preferred electronic elements are transistors. Preferably the film acts as chemical barrier metal in a transistor. A chemical barrier metal is a material reduces diffusion of adjacent layers while maintaining electrical connectivity.

The compounds of general formula (Ia), (Ib), (Ic), (Id), (IIa), (IIb), (IIc), or (IId) are particularly suitable as reducing agents in an ALD process. Therefore, the present invention relates to a compound of general formula (Ia), (Ib), (Ic), (Id), (IIa), (IIb), (IIc), or (IId). The same definitions and preferred embodiments as for the process described above apply for the compounds, in particular the preferred examples in table 1 to 8.

### BRIEF DESCRIPTION OF THE FIGURES

FIG. 1 shows the thermogravimetric analysis of compound Ia-1. The mass loss at 180° C. is 98.77%.

FIG. 2 shows the thermogravimetric analysis of compound Ic-1. The mass loss at 150° C. is 97.63%.

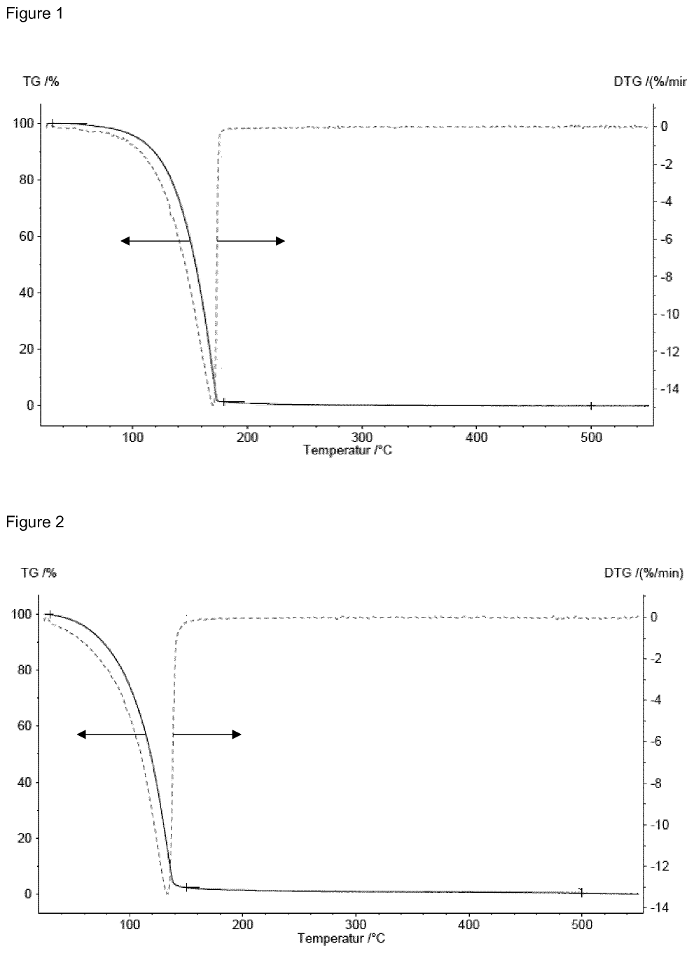

1. A process for preparing a metal-comprising film, the process comprising:
(a) depositing a metal-comprising compound from a gaseous state onto a solid substrate and
(b) contacting the deposited metal-comprising compound with a compound of general formula (Ia), (Ib), (Ic), (Id), (IIa), (IIb), (IIc), or (IId) 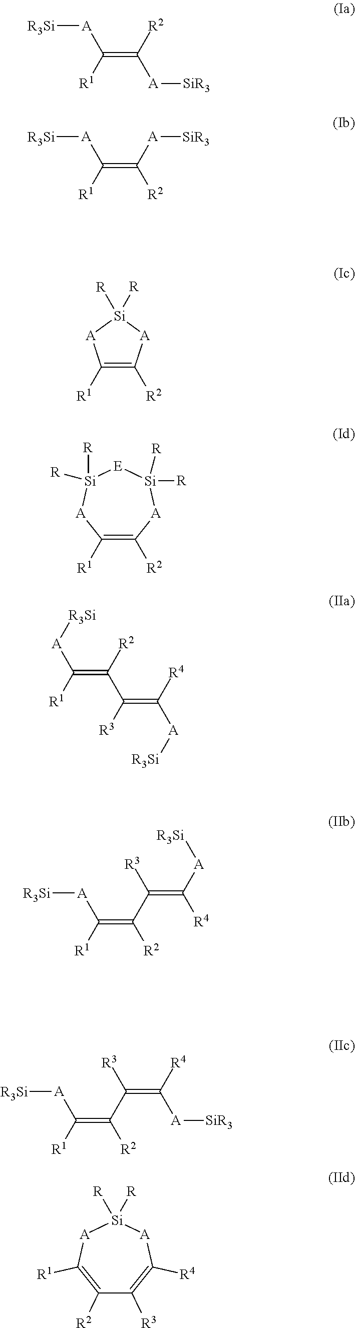
wherein A is O or NR^{N},
each of R and R^{N} is independently hydrogen, an alkyl group, an alkenyl group, an aryl group, or a silyl group,
each of R¹, R², R³, and R⁴ is independently hydrogen, an alkyl group, an alkenyl group, an aryl group, a silyl group, or an ester group, and
E is nothing, oxygen, methylene, ethylene, or 1,3-propylene.

2. The process of claim 1, wherein R is hydrogen or methyl.

3. The process of claim 1, wherein A is NR^{N} and R^{N} is an alkyl group or a silyl group.

4. The process of claim 1, wherein A is NR^{N} and R^{N} is tert-butyl, neo-pentyl, 2,6-dimethylphenyl or trimethylsilyl.

5. The process of claim 1, wherein each of R¹, R², R³ and R⁴ is independently hydrogen, methyl, tert-butyl, trimethylsilyl or methylcarboxylate.

6. The process of claim 1, wherein the compound of general formula (Ia), (Ib), (Ic), (Id), (IIa), (IIb), (IIc), or (IId) has a molecular weight of not more than 600 g/mol.

7. The process of claim 1, wherein the reducing agent the compound of general formula (Ia), (Ib), (Ic), (Id), (IIa), (IIb), (IIc), or (IId) has a vapor pressure of at least 0.1 mbar at 200° C.

8. The process of claim 1, wherein (a) and (b) are successively performed at least twice.

9. The process of claim 1, wherein the metal-comprising compound comprises Ti, Ta, Mn, Mo, W, or Al.

10. The process of claim 1, wherein a temperature does not exceed 350° C.

11. A reducing agent, suitable for a film forming process and comprising the compound of general formula (Ia), (Ib), (Ic), (Id), (IIa), (IIb), (IIc), or (IId) of claim 1.

12. A compound of general formula (Id), 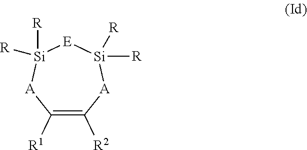
wherein A is O or NR^{N},
each of R and R^{N} is independently hydrogen, an alkyl group, an alkenyl group, an aryl group, or a silyl group,
each of R¹ and R² is independently hydrogen or an alkyl group, and
E is nothing, oxygen, methylene, ethylene, or 1,3-propylene.

13. A compound of general formula (IIa), (IIb), (IIc) or (IId), 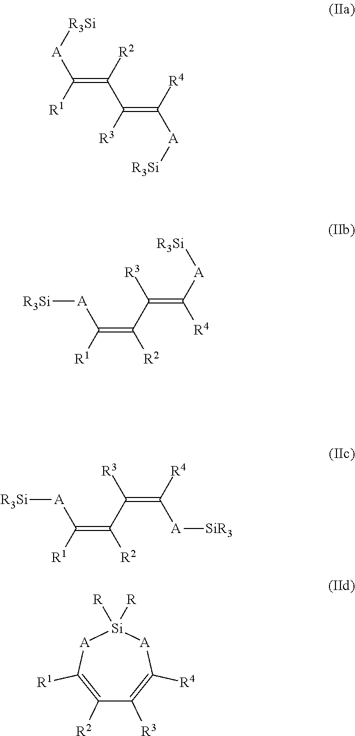
wherein A is NR^{N},
each of R and R^{N} is independently hydrogen, an alkyl group, an alkenyl group, an aryl group, or a silyl group, and
each of R¹, R², R³, and R⁴ is independently hydrogen, an alkyl group, an alkenyl group, an aryl group, a silyl group, or an ester group in the case of general formula (IIa), (IIb), and (IIc), and an alkyl group, an alkenyl group, an aryl group, or a silyl group in the case of general formula (IId).
